(19) United States
(12) Patent Application Publication
(10) Pub. No.: US 2016/0011283 A1
(43) Pub. Date: Jan. 14, 2016

(54) ACCELERATING FIRST ORDER REVERSAL CURVE DISTRIBUTION MEASURMENTS

(71) Applicant: Magnetic Daneshpajoh Kashan Company, Kashan (IR)

(72) Inventors: Mohammad Almasi Kashi, Kashan (IR); Elham Jafari-Khamse, Karaj (IR); Abdolali Ramazani, Kashan (IR); Samira Samanifar, Saman (IR)

(21) Appl. No.: 14/859,817

(22) Filed: Sep. 21, 2015

Related U.S. Application Data
(60) Provisional application No. 62/052,724, filed on Sep. 19, 2014.

(51) Int. Cl. G01R 33/14; G01N 27/72

(52) U.S. Cl. CPC G01R 33/14; G01N 27/72

(57) ABSTRACT

A method for accelerating first order reversal curve (FORC) distribution measurement of a sample is disclosed. The method includes steps of obtaining a sample; setting an interpolation direction; setting an applied field step and a reversal field step based on the interpolation direction; obtaining a set of FORCs with the applied field step and the reversal field step; and executing an interpolation algorithm using a computing device to interpolate missing data in the interpolation direction, thereby accelerating calculation of the FORC distribution of the sample.

### CROSS REFERENCE TO RELATED APPLICATION

The present application claims priority from pending U.S. Provisional Patent Application Ser. No. 62/052,724, filed Sep. 19, 2014, entitled “A method for First-Order-Reversal-Curve (FORC) Measurement acceleration,” the subject matter of which is incorporated by reference herein in its entirety.

### SPONSORSHIP STATEMENT

This application has been sponsored by the Iranian Nanotechnology Initiative Council, which does not have any rights in this application.

### TECHNICAL FIELD

The present application generally relates to first order reversal curve (FORC) measurements, and more particularly to calculating FORC distributions from experimental hysteresis data, and even more particularly to a method for accelerating the calculation of FORC distributions.

### BACKGROUND

To access the magneto-static properties of a system, one usually uses a magnetometer to measure the major hysteresis curve. It is possible to use the same experimental setup to obtain the local magneto-static properties of the system, by measuring multiple minor hysteresis curves, called first-order reversal curves (hereinafter “FORCs”).

Using FORC diagrams is becoming an increasingly popular method of studying coercivity and interaction spectra in fine particle magnetic systems. The ability to define these spectra accurately, results in a detailed magnetic characterization of a material, and provides an insight into the sample, which is not available from a standard hysteresis loop, especially, in case of nanostructured systems, in which, the information from the distribution of the local properties are more important than the average properties obtained from common hysteresis curves. FORC diagrams make it possible to determine the detailed information from the domain states and hysteretic properties of the ferromagnetic systems and generally any form of the hysteretic dependence of the materials.

As is known from the prior art, a set of FORCs is measured by a magnetometer in a procedure as follows: first, the sample is taken from a positively saturating field to a lower or negative reversal field (defined hereinafter as “Hᵣ”); then the applied field (defined hereinafter as “H”) is increased with specific intervals (hereinafter “applied field steps” and defined as “ΔH”), and in each interval the magnetization of the sample is measured using a magnetometer, until the applied field reaches the saturating field of the sample; after that, the reversal field is increased by a specific interval (hereinafter “reversal field step” and defined as “ΔHᵣ”), the sample is taken from the saturating field to this new reversal point and then, the applied field is increased in a stepwise manner with ΔH as the interval between each step until the applied field reaches the saturating field. At each step, the magnetization is measured by a magnetometer, and a second FORC is obtained. As is known to those skilled in the art, this repetitive procedure is carried out until the whole hysteresis curve of the sample is covered by the measured FORCs. The aforementioned set of FORCs are, in fact, magnetization data as a function of H and Hᵣ. The magnetization measured in this manner is generally denoted as M (Hᵣ, H). It should be understood by those skilled in the art, that the term “field” used hereinabove, refers to a “magnetic field”.

Once the magnetization data have been measured, as a set of FORCs, following the repetitive procedure described in detail hereinabove, the FORC distribution (defined as “p”) can be obtained via calculating the mixed second derivative of the magnetization data as follows:

$$ρ = - \frac{1}{2} \frac{{\partial }^{2} M ( H , {H}_{r} )}{\partial H \partial {H}_{r}}$$

Afterwards, the calculated FORC distribution is plotted in rotated coordinates from {Hᵣ, H} to {(Hᵣ+H)/2, (Hᵣ−H)/2}. A FORC diagram is a counter plot of a calculated FORC distribution in the aforementioned rotated coordinates.

A number of different methods have previously been introduced in the art to calculate FORC distributions from experimental magnetization data. In a number of cases, the mixed second derivative is simply calculated directly. But, this approach has the known drawback of tending to have a large noise contribution, which can mask smaller features in the data.

Different methods have been suggested in the art to improve the quality of the obtained FORC distributions. Most of these methods either lead to a longer measurement time or larger errors in measurements.

As is known to a person skilled in the art, one of the major drawbacks of using FORC distributions, is the long measurement time required to obtain the magnetization data, from which, the FORC distributions are calculated. This long measurement procedure puts an overwhelming pressure on the measurement equipment.

Different methods are suggested in the art to reduce the measurement time required to obtain a FORC diagram. The measurement time depends on parameters like the applied field step, the magnitude of the sample's saturation field, and the average measurement time for each data point. Increasing the applied field step, reduces the measurement time, but leads to a lower quality of the FORC diagrams. The magnitude of the saturation field depends on the sample, if the saturation field required for a particular sample is high, the time required to obtain a FORC diagram for that sample is longer. Reducing the average measurement time for each data point, reduces the total measurement time, but leads to a lower quality of the FORC diagrams.

Therefore, there is a need in the art, to reduce the measurement time required to obtain a FORC diagram, while maintaining the quality of the aforementioned diagram. Manipulating all the parameters mentioned hereinabove, like the applied field step or the average measurement time for each data point, can reduce the measurement time but at the expense of losing valuable details in the diagrams. The appearance of mechanical noise in the measured data is yet another drawback, which makes it difficult to obtain high quality FORC distributions.

Hence, there is a need to reduce the measurement time required for obtaining a FORC diagram, while maintaining the quality of the diagram. A shorter measurement time is beneficial to the measurement equipment, generally used to measure the magnetization data as a function of the applied field and the reversal field.

Additionally, there is a need to reduce the effect of mechanical noise in the data and improve the quality of the obtained FORC diagram.

### SUMMARY

The following brief summary is not intended to include all features and aspects of the present application, nor does it imply that the application must include all features and aspects discussed in this summary.

The present application relates to a method for the acceleration of FORC measurements, while maintaining the quality of the resultant FORC distributions. According to implementations of the present application, the number of data points measured for the given sample are reduced, which leads to a shorter measurement time, and the missing data required for obtaining a high quality FORC distribution are interpolated using the aforementioned measured data points. Therefore, the measurement time can be reduced, while the quality of the resultant FORC distribution can be maintained.

According to one general aspect of the present application the method for accelerating FORC distribution measurements is carried out by the following steps: first, a sample is provided and second, an interpolation direction is chosen based on the behavior of the sample. The interpolation direction can be the applied field direction, the reversal field direction, or both. If, for example, the applied field direction is chosen to be the interpolation direction, it means that the missing data are interpolated only in this direction. In contrast, if the reversal field direction is chosen to be the interpolation direction, it means that the missing data are interpolated only in the reversal field direction.

Moving forward, the third step includes choosing ΔH and ΔHᵣ according to the interpolation direction. For example, if the applied field is chosen to be the interpolation direction, ΔH is chosen to be sufficiently large in order to reduce the number of measured data points in this direction only. For another example, if the reversal field is chosen to be the interpolation direction, ΔHᵣ is chosen to be sufficiently large in order to reduce the number of measured data points in this direction only.

Moving forward, the fourth step includes measuring a set of FORCs or a set of magnetization data as a function of H and Hᵣ by a magnetometer using the set ΔH and ΔHᵣ. The fifth step includes interpolating missing data due to the large field steps chosen in the interpolation direction using a fitting formula and finally, the FORC distribution is calculated by obtaining a second mixed derivative of the magnetization data, using the fitting formula obtained in the previous step.

The above general aspect may include one or more of the following features. A vibrating sample magnetometer may be used to measure the magnetization data or the set of FORCs. A spline interpolation method may be used to interpolate the missing magnetization data in the interpolation direction.

In another general aspect of the present application a device is used for accelerated FORC distribution measurement of a sample. The device includes a magnetometer configured to provide magnetization data; a processor; and a memory coupled to the processor and configured to store a repetitive first order reversal curve (FORC) measurement procedure and an interpolation algorithm. The memory is further configured to store executable instructions for causing the processor to: receive the magnetization data; execute the repetitive FORC procedure to: set an interpolation direction; set an applied field step and a reversal field step based on the interpolation direction; measure a set of FORCs or magnetization data with the applied field step and the reversal field step using the magnetometer; and store the set of FORCs or the magnetization data in the memory; and execute the interpolation algorithm to: receive the measured FORCs or the magnetization data; fit the magnetization data using a fitting method to obtain a fitting formula; interpolate missing data using the obtained fitting formula; and calculate the FORC distribution using the measured and interpolated magnetization data via calculating a mixed second derivative of the magnetization data using the fitting formula.

In another general aspect, the instant application describes an article of manufacture including a non-transitory computer-readable medium and a computer program for causing a computer to obtain first order reversal curve (FORC) distributions of a sample using magnetization data received from a magnetometer, the computer program being embodied on the computer-readable medium and including instructions that, when executed, cause the computer to: fit the magnetization data to obtain a fitting formula; interpolate missing data using the obtained fitting formula; and calculate the FORC distribution.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIG. 1 illustrates a block diagram of an exemplary system that utilizes a method for accelerating FORC distribution measurements according to one implementation.

FIG. 2 illustrates a schematic diagram of an exemplary vibrating sample magnetometer according to an implementation of the present application.

FIG. 3A-3H illustrates exemplary FORC diagrams of FeCO nanowires, obtained from: direct measurements with small field steps with a smoothing factor of 1 (FIG. 3A); direct measurements with small field steps with a smoothing factor of 2 (FIG. 3B); direct measurements with large field steps in the applied field direction, interpolating the missing data in the applied field direction with a smoothing factor of 1 (FIG. 3C); direct measurements with large field steps in the applied field direction, interpolating the missing data in the applied field direction with a smoothing factor of 2 (FIG. 3D); direct measurements with large field steps in the reversal field direction, interpolating the missing data in the reversal field direction with a smoothing factor of 1 (FIG. 3E); direct measurements with large field steps in the reversal field direction, interpolating the missing data in the reversal field direction with a smoothing factor of 2 (FIG. 3F); direct measurements with large field steps in both the reversal field and the applied field directions, interpolating the missing data in both directions with a smoothing factor of 1 (FIG. 3G); direct measurements with large field steps in both the reversal field and the applied field directions, interpolating the missing data in both directions with a smoothing factor of 2 (FIG. 3H).

### DETAILED DESCRIPTION

In the following detailed description, numerous specific details are set forth by way of examples in order to provide a thorough understanding of the relevant teachings. However, it should be apparent that the present teachings may be practiced without such details. In other instances, well known methods, procedures, components, and/or circuitry have been described at a relatively high-level, without detail, in order to avoid unnecessarily obscuring aspects of the present teachings.

For purposes of explanation, specific nomenclature is set forth to provide a thorough understanding of the present application. However, it will be apparent to one skilled in the art that these specific details are not required to practice the application. Descriptions of specific applications are provided only as representative examples. Various modifications to the preferred implementations will be readily apparent to one skilled in the art, and the general principles defined herein may be applied to other implementations and applications without departing from the scope of the application. The present application is not intended to be limited to the implementations shown, but is to be accorded the widest possible scope consistent with the principles and features disclosed herein.

It should be understood by a person skilled in the art that the present application is directed to and designed for the acceleration of FORC measurements, while maintaining the quality of the resultant FORC distributions. According to the teachings of the present application, which are described in more detail hereinbelow, the number of data points measured for the given sample are reduced, which leads to a shorter measurement time, and the missing data required for obtaining a high quality FORC distribution are interpolated using the aforementioned measured data points. Therefore, the measurement time is reduced, while the quality of the resultant FORC distribution is maintained.

According to the teachings of the present application, the accelerated repetitive FORC measurement procedure may be carried out by the following steps: first, a sample may be provided; second, an interpolation direction may be chosen based on the behavior of the sample. The interpolation direction may be the applied field direction, the reversal field direction, or both. If, for example, the applied field direction is chosen to be the interpolation direction, it means that the missing data are interpolated only in this direction. Similarly, if the reversal field direction is chosen to be the interpolation direction, it means that the missing data are interpolated only in this reversal field direction.

Third, ΔH and ΔHᵣ may be chosen according to the interpolation direction. If, for example, the applied field is chosen to be the interpolation direction, ΔH may be chosen to be sufficiently large, in order to reduce the number of measured data points in this direction and the missing data are interpolated using a fitting formula. Similarly, if, for example, the reversal field is chosen to be the interpolation direction, ΔHᵣ may be chosen to be sufficiently large, in order to reduce the number of measured data points in this direction only. Fourth, a set of FORCs or a set of magnetization data as a function of H and Hᵣ may be measured by a magnetometer using the set ΔH and ΔHᵣ in a repetitive procedure for obtaining a set of FORCs, as is known in the art. Then, the missing data due to the large field steps chosen in the interpolation direction may be interpolated using a fitting formula. Finally, the FORC distribution may be calculated by obtaining the second mixed derivative of the magnetization data, using the fitting formula obtained in the previous step.

It is known to those skilled in the art, that using large intervals between the applied field steps and the reversal field steps, significantly reduces the measurement time, but leads to loosing valuable details in the FORC distribution. According to the present application, the missing details due to a lower number of measured data points can be compensated by interpolating the lost data points with a simple regression method. Using the regression method, new data can be constructed within the range of the measured data points. In other words, the regression method, provides a means for estimating the magnetization of the sample at intermediate points.

Using the regression method, a magnetization function may be fitted over the measured data, which may then be used for interpolating and inserting new data points in between the measured data points. Then, the same regressed magnetization function may be used to calculate the mixed second derivative of the magnetization at each data point, and thereby obtaining the FORC distribution.

Many different regression methods are known in the art. One of the most precise regression methods is the spline regression. The goal of the spline regression is to obtain a continuous interpolation formula in both the first and second derivatives, both within the intervals and at the interpolating data points. It results in a smooth interpolating function, which can be used to insert the missing data points.

As is known in the art, in a spline regression method, a piece-wise low-order polynomial fitting procedure is utilized to obtain a smooth trend surface over the measured data points. This fitted function can be used to insert the missing data between each pair of the measured data points. Since the magnetization is a function of both the reversal field (Hᵣ) and the applied field (H), a local grid can be defined in Hᵣ, H coordinate system. The local grid is composed of points from consecutive data points from consecutive FORCs with a side equal to 2SF+1, where SF is any given positive integer smoothing factor.

In one implementation of the present application, a second order trend surface of the form a₁+a₂Hᵣ+a₃Hᵣ²+a₄H+a₅H²+a₆HᵣH is fitted to the magnetization data in the aforementioned local grid in a least-squares manner, and the value of −a₆ provides the mixed second derivative of the fitted magnetization surface and can be assigned to the center of the local grid as a representation of the density of FORC distribution at that point.

Each coefficient in the fitted function may be determined considering the following conditions: the value obtained from the fitted function in each data point must be equal to that obtained from direct measurements at that particular point; first and second derivatives of the fitted function must be continuous in each data point and equal to the first and the second derivatives of the entire FORC; and first, second, and third derivatives of the fitted function must be zero in the extremes. Therefore, at most, half of the data points are actually obtained from magnetization measurements, while the rest of the data points are interpolated using a spline regression method, which reduces the measurement time and the work load on the magnetometer significantly.

The interpolation can be carried out in the reversal field direction, the applied field direction, or in both directions. ΔH and ΔHᵣ can either be equal or of different sizes. Generally, ΔH and ΔHᵣ are chosen to be equal, in this manner, the measurement time is shorter. However, as is known in the art, since different samples have different behaviors, in order to obtain a high quality FORC diagram, it may be better to use different reversal field steps and applied field steps based on the behavior of the sample in each direction. When the reversal field and the applied field are not equally spaced, in common methods for obtaining the FORC distribution, the measurement time increases significantly, but with the method of the present application, since the number of the measured data points are lower, choosing unequal ΔHᵣ and ΔH does not increase the measurement time.

The spline regression procedure includes the steps of: first, obtaining a set of measured FORCs, which are a set of magnetization data as a function of the applied field and the reversal field; second, fitting the measured magnetization data via a spline fitting procedure and obtaining a fitting formula, as described hereinabove; third, interpolating the missing data using the fitting formula; and finally, calculating the second mixed derivative of the measured and interpolated magnetization data using the fitted formula and thereby transforming the magnetization data into a FORC distribution data.

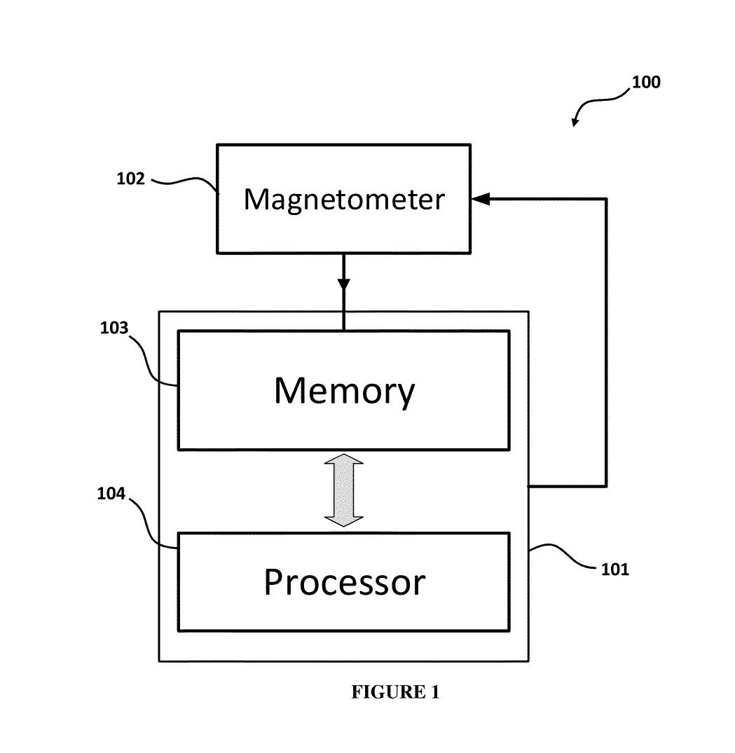

With this overview, the teachings of the present application are now described with respect to the illustrated drawings. FIG. 1 illustrates an exemplary block diagram of a system 100 for accelerated measurement of FORC distributions of a sample according to one implementation of the present application. The system 100 includes a computer device 101 and a magnetometer 102. The computer device 101 may include any type of electronic devices capable of storing and processing data. The computer device 101 receives input data from a magnetometer 102. The computer device 101 includes a memory 103 for storing data. The data received from the magnetometer 102 are stored in the memory 103 as a set of magnetization data. The memory 103 also includes an accelerated repetitive FORC measurement procedure and an interpolation algorithm in accordance with the present application. A processor 104 first executes the repetitive FORC measurement procedure, whereby a set of FORCs or a set of magnetization data is measured by the magnetometer 102 and stored in the memory 103. Then, the processor 104 executes the interpolation algorithm, which operates on the set of magnetization data stored in the memory, thereby calculating FORC distributions. In this manner, the process of measuring and calculating the FORC distributions of a sample is accelerated using the system 100 described hereinabove. Due to the reduced number of measurements, the work load of the magnetometer 102 used in this system 100 is much lower than that of ordinary magnetometers, which are commonly used in the art.

It should be understood by those skilled in the art that different types of magnetometers, such as an alternating gradient force magnetometer, a vibrating sample magnetometer (VSM) and etc. can be utilized to measure the magnetization of the sample or the material under study. Therefore, all different types of magnetometers or experimental devices used to measure the magnetization of a sample are in the scope of the present application. According to one implementation of the present application, a VSM is used to measure the magnetization of the sample or the material under study.

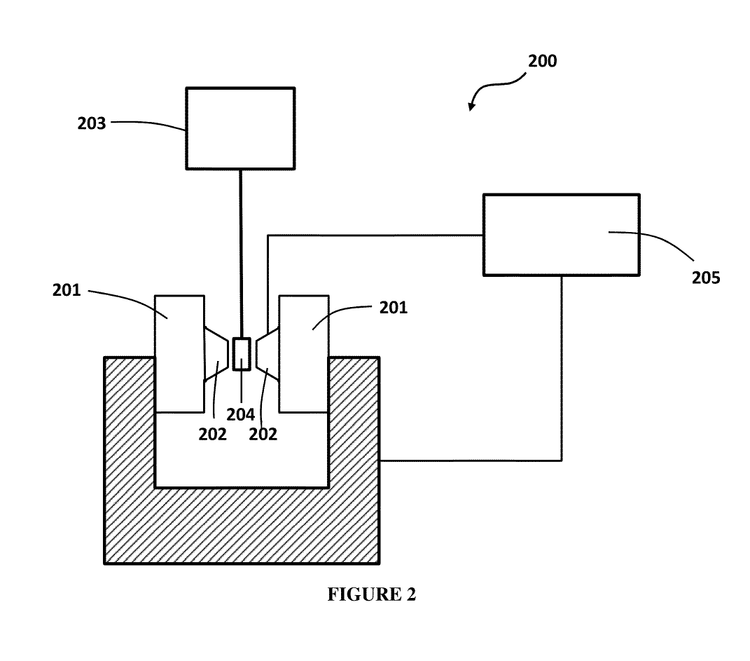

FIG. 2 illustrates an exemplary schematic diagram of a VSM according to one implementation of the present application. The magnetometer 200 includes a pair of spaced apart, field-controlled electromagnet coils 201, a pair of pickup coils 202, and an electric vibrator 203. The coils 201 may be operated to produce a homogeneous magnetic field. The electric vibrator 203 may be configured to vibrate the sample 204 in the homogeneous applied field produced by the electromagnet coils 201. The vertical vibration of the sample 204 may result in a change in the magnetic flux that is detected by the pickup coils 202. The induced voltage in the pickup coils 202 may then related to the magnetization of the sample, with a simple calibration coefficient which, as is known in the art, may be determined experimentally using a known standard magnetic sample. The magnetization data may be sent to a computer device 105, which includes a memory and a processor. The data received from the magnetometer is stored in the memory of the computer device 105.

### Example

### Accelerated FORC Distribution Measurement of FeCo Nanowire

In this implementation, FORC distribution of a sample of FeCO nanowire, electro-deposited into a porous aluminum oxide template, is obtained using the accelerated method of the present application. Four sets of measurements were used to obtain the FORC distributions of the FeCO nanowire: first, with small equal ΔH and ΔHᵣ of 125 Oe, which is a common time-consuming method widely used in the art; second, with large ΔH of 250 Oe, and small ΔHᵣ of 125 Oe, and interpolating the missing data in the applied field direction, using the interpolation method of the present application; third, with large ΔHᵣ of 250 Oe, and small ΔH of 125 Oe, and interpolation the missing data in the reversal field direction, using the interpolation method of the present application; and finally, with large field steps of 250 Oe in both applied field and reversal field directions, and interpolating the missing data in both directions. In order to carry out the interpolation procedure of the present application and FORC distribution calculation in each of the above described measurement procedures, two smoothing factors of 1 and 2 were used.

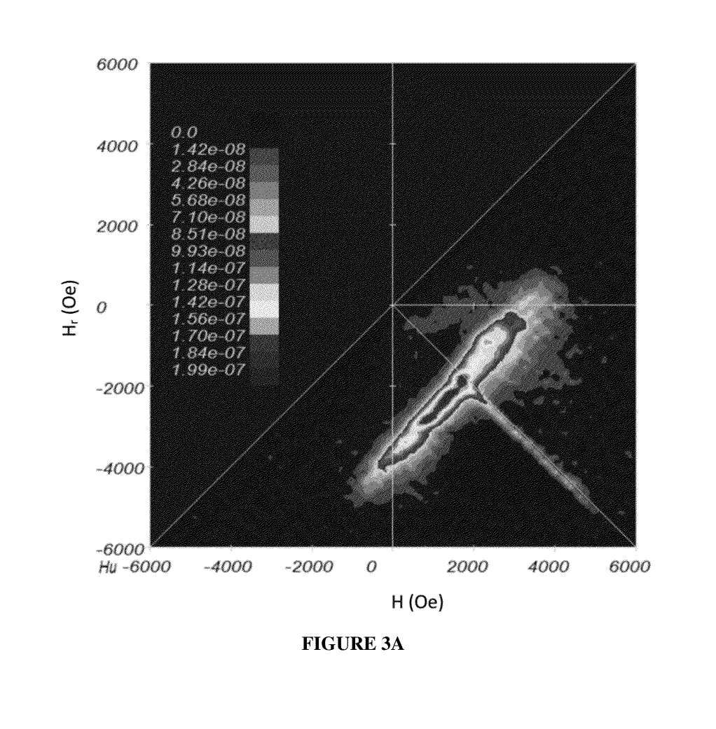

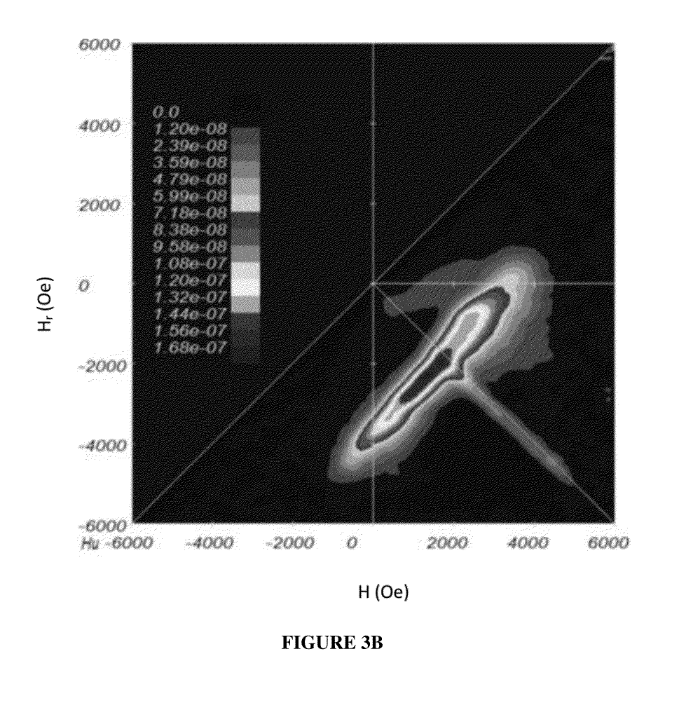

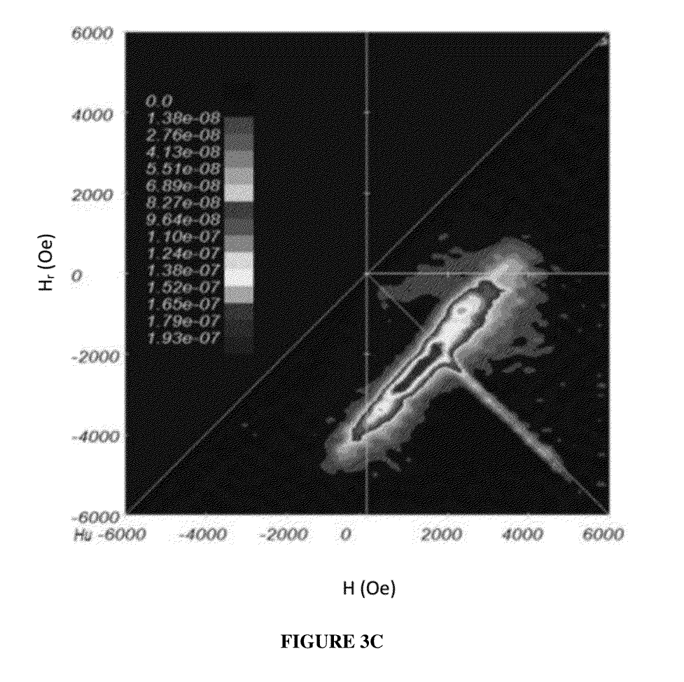

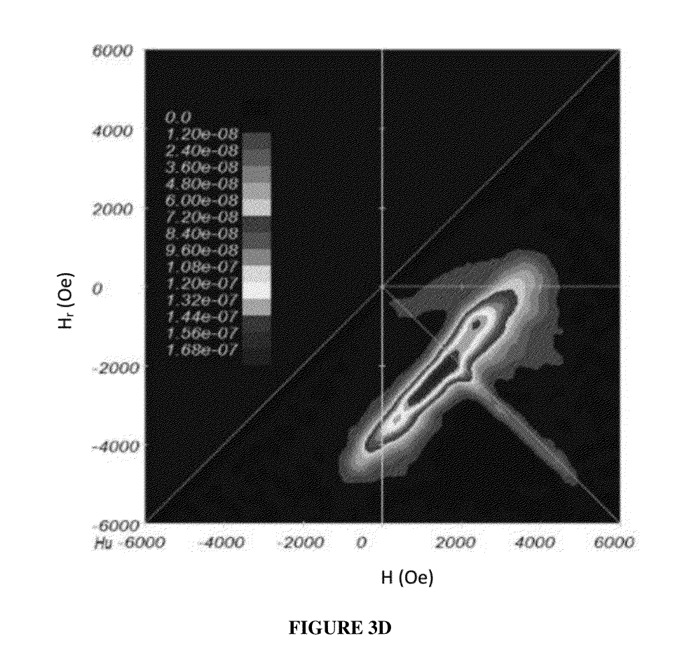

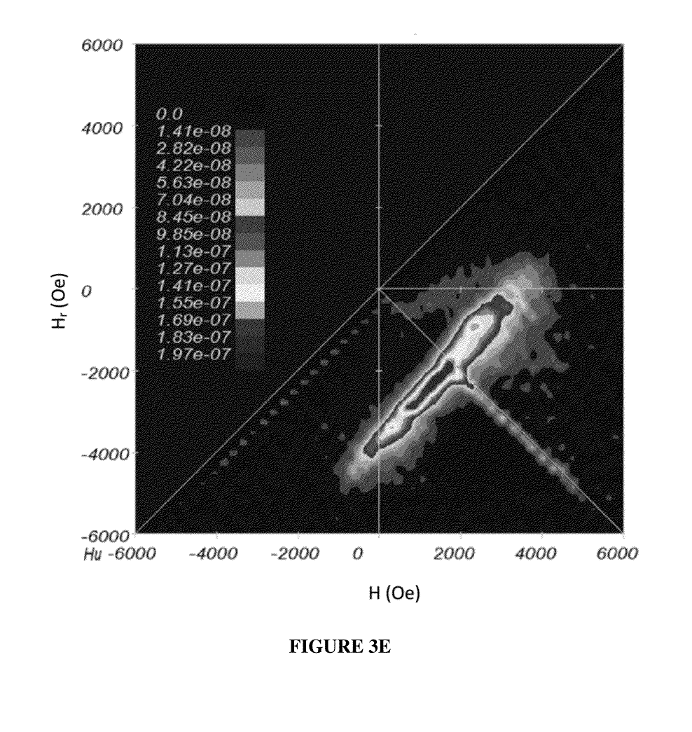

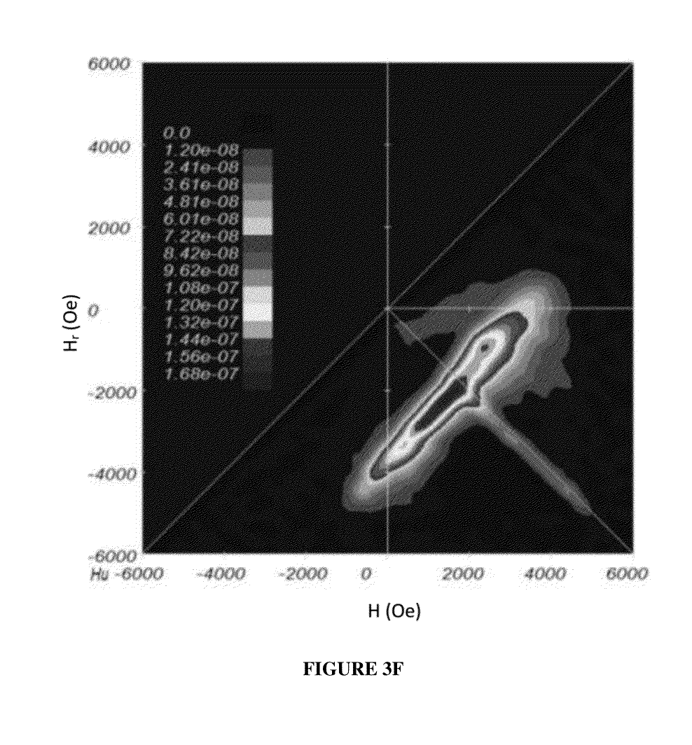

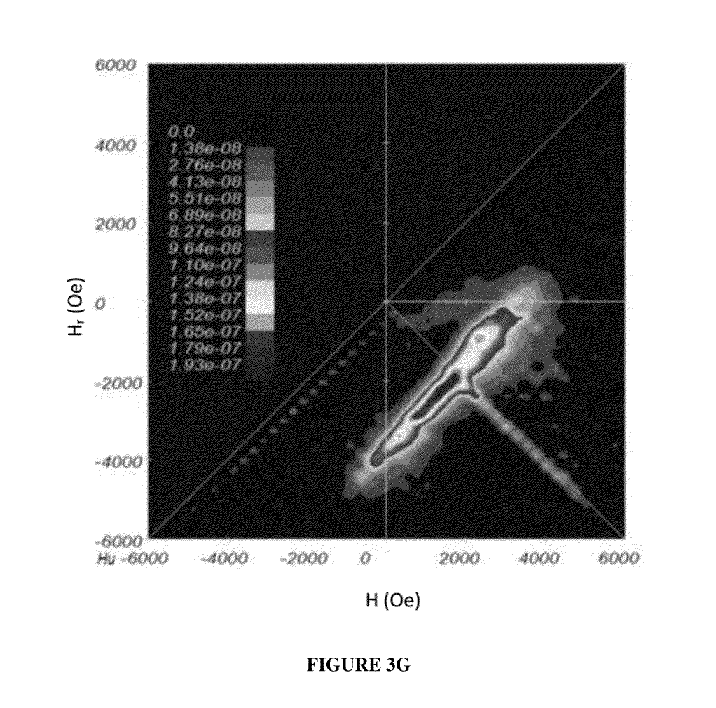

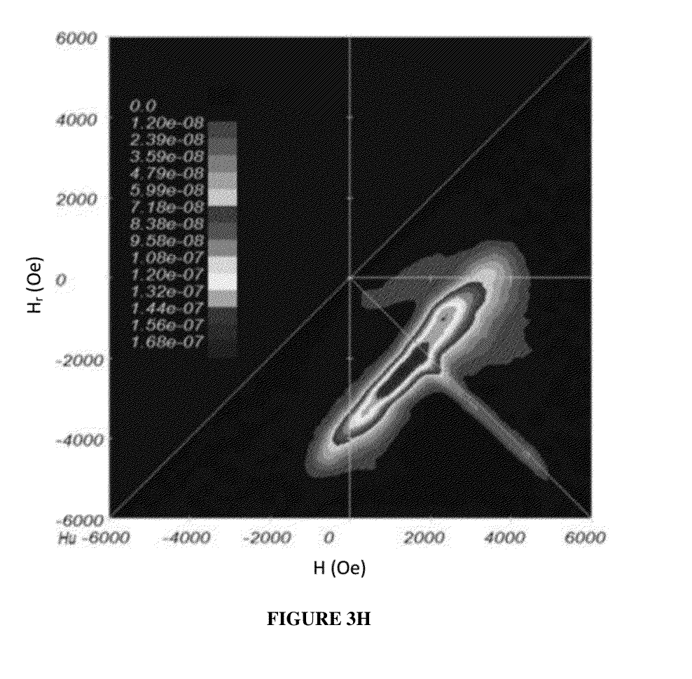

The FORC diagram of FeCO nanowire is illustrated in the implementation of FIGS. 3A to 3H of the DRAWINGS. As discussed in more detail hereinabove, a FORC diagram is the calculated FORC distribution data of the sample, plotted in the rotated coordinates of {(H+Hᵣ)/2, (H−Hᵣ)/2}. As can be seen in these figures, the vertical axis shows the reversal field (Hᵣ), the horizontal axis shows the applied field (H), and the FORC distribution of the sample obtained in each point is shown by a gray scale color gradient. Each color represents an amount of FORC distribution at each point; both the color codes and the magnitudes of FORC distributions assigned to each color are clearly shown in each figure. FIG. 3A shows the FORC diagram which is directly measured for the FeCO nanowire sample with small field steps of 125 Oe in both reversal field and applied field directions, with a smoothing factor (SF) of 1, without performing the interpolation procedure. The saturation field for FeCO nanowire sample is about 6000 Oe. It may take around 11 hours to obtain this diagram using a VSM.

FIG. 3B illustrates a FORC diagram obtained in the same manner as with FIG. 3A, but in this figure, the FORC distribution is calculated with a smoothing factor of 2, which may result in a smoother diagram at the cost of losing some details.

FIG. 3C of the DRAWINGS illustrates the FORC diagram obtained for the FeCO nanowire sample, with the interpolation procedure carried out only in the applied field direction. The smoothing factor used for calculating the FORC distribution in this figure is 1. FIG. 3D illustrates the same FORC diagram as with FIG. 3C, but the FORC distribution calculation is carried out with a smoothing factor of 2. It may take around 3 hours to obtain the FORC diagram.

FIG. 3E of the DRAWINGS illustrates the FORC diagram obtained for the FeCO nanowire sample, with the interpolation procedure carried out only in the reversal field direction, the smoothing factor used for calculating the FORC distribution in this figure is 1. FIG. 3F illustrates the same FORC diagram as with FIG. 3E, but the FORC distribution calculation is carried out with a smoothing factor of 2. It may take around 3 hours to obtain the FORC diagram.

FIG. 3G of the DRAWINGS illustrates the FORC diagram obtained for the FeCO nanowire sample, with the interpolation procedure carried out in both the reversal field and the applied field directions. The smoothing factor used for calculating the FORC distribution in this figure is 1. FIG. 3H illustrates the same FORC diagram as with FIG. 3G, but the FORC distribution calculation is carried out with a smoothing factor of 2. It takes around 5 hours to obtain the FORC diagram.

In order to compare the quality of the FORC diagrams obtained in different conditions described in detail hereinabove, the volume under the surface of the FORC distribution obtained in each measurement is obtained via integration. The integration data is presented and set forth in TABLE 1 hereinbelow.

TABLE 1

| Direct | | | | | | | |
|---|---|---|---|---|---|---|---|
| measurement | | Interpolation | | Interpolation | | Interpolation | |
| with small | | in reversal | | in applied | | in both | |
| field steps | | field direction | | field direction | | directions | |
| SF = 1 | SF = 2 | SF = 1 | SF = 2 | SF = 1 | SF = 2 | SF = 1 | SF = 2 |
| 0.78 | 0.84 | 0.76 | 0.89 | 0.71 | 0.80 | 0.70 | 0.80 |

The volume under the FORC distribution surface can be a good measure of the quality of the FORC diagram. As is presented in TABLE 1 hereinabove, the quality of the obtained FORC diagrams using the interpolation procedure of the present application is comparable to that of the FORC diagrams obtained with smaller field steps. This means that utilizing the method of the present application, significantly reduces the measurement time, while maintaining the overall quality of the FORC diagrams.

With reference now to TABLE 2, presented hereinbelow, this TABLE presents the maximum FORC distribution obtained in all 8 sets of data obtained from the measurements of the EXAMPLE. As can be seen in this table, the maximum FORC distribution of the obtained FORC diagrams using the interpolation procedure of the present application is comparable to that of the FORC diagrams obtained with smaller field steps. This means, utilizing the method of the present application significantly reduces the measurement time, while maintaining the overall quality of the FORC diagrams.

TABLE 2

| Direct | | | | | | | |
|---|---|---|---|---|---|---|---|
| measurement | | Interpolation | | Interpolation | | Interpolation | |
| with small | | in reversal | | in applied | | in both | |
| field steps | | field direction | | field direction | | directions | |
| SF = 1 | SF = 2 | SF = 1 | SF = 2 | SF = 1 | SF = 2 | SF = 1 | SF = 2 |
| 1.99E−7 | 1.68E−7 | 1.93E−7 | 1.68E−7 | 1.97E−7 | 1.68E−7 | 1.93E−7 | 1.68E−7 |

While the present application has been illustrated by the description of the implementations thereof, and while the implementations have been described in detail, it is not the intention of the applicant to restrict or in any way limit the scope of the appended claims to such detail. Additional advantages and modifications will readily appear to those skilled in the art. Therefore, the application in its broader aspects is not limited to the specific details, representative apparatus and method, and illustrative examples shown and described. Accordingly, departures may be made from such details without departure from the breadth or scope of the applicant's concept. Furthermore, although the present application has been described in connection with a number of exemplary implementations and implementations, the present application is not so limited but rather covers various modifications and equivalent arrangements, which fall within the purview of the appended claims.

What is claimed is:

1. A method for accelerating first order reversal curve (FORC) distribution measurement of a sample, the method comprising steps of:
obtaining a sample;
setting an interpolation direction;
setting an applied field step and a reversal field step based on the interpolation direction;
obtaining a set of FORCs with the applied field step and the reversal field step; and
executing an interpolation algorithm using a computing device to interpolate missing data in the interpolation direction, thereby accelerating calculation of the FORC distribution of the sample.

2. The method according to claim 1, wherein the interpolation direction is selected from a group consisting of the applied field direction, the reversal field direction, or both.

3. The method according to claim 1, wherein obtaining the set of FORCs with the applied field step and the reversal field step is carried out using a magnetometer.

4. The method according to claim 3, wherein the magnetometer is a vibrating sample magnetometer.

5. The method according to claim 1, wherein executing the interpolation algorithm includes steps of:
receiving via the computing device obtained set of FORCs or a set of measured magnetization data;
fitting via the computing device the measured magnetization data using a fitting method to obtain a fitting formula;
interpolating via the computing device the missing data using the obtained fitting formula; and
calculating via the computing device the FORC distribution using the measured and interpolated magnetization data via calculating a mixed second derivative of the measured magnetization data using the fitting formula.

6. The method according to claim 5, wherein the fitting method is a spline fitting method.

7. A device for accelerating FORC distribution measurement of a sample, the device comprising:
a magnetometer configured to provide magnetization data;
a processor; and
a memory coupled to the processor and configured to store a repetitive first order reversal curve (FORC) measurement procedure, an interpolation algorithm, and executable instructions for causing the processor to:
receive the magnetization data;
execute the repetitive FORC procedure to:
set an interpolation direction;
set an applied field step and a reversal field step based on the interpolation direction;
measure a set of FORCs or magnetization data with the applied field step and the reversal field step using the magnetometer; and
store the set of FORCs or the magnetization data in the memory; and
execute the interpolation algorithm to:
receive the measured FORCs or the magnetization data;
fit the magnetization data using a fitting method to obtain a fitting formula;
interpolate missing data using the obtained fitting formula; and
calculate the FORC distribution using the measured and interpolated magnetization data via calculating a mixed second derivative of the magnetization data using the fitting formula.

8. The device according to claim 7, wherein the interpolation direction is selected from a group consisting of the applied field direction, the reversal field direction, or both.

9. The device according to claim 7, wherein the applied field step is set with a sufficiently large interval, when the interpolation direction is the applied field direction, in order to reduce the amount of measured data points in the applied filed direction.

10. The device according to claim 7, wherein the reversal field step is set with a sufficiently large interval, when the interpolation direction is the reversal field direction, in order to reduce the amount of measured data points in the reversal field direction.

11. The device according to claim 7, wherein both reversal field step and the applied field step are set with sufficiently large intervals, when the interpolation direction is both the reversal field and the applied field directions, in order to reduce the amount of measured data points in both directions.

12. The device according to claim 7, wherein the magnetometer is a vibrating sample magnetometer.

13. An article of manufacture comprising a non-transitory computer-readable medium and a computer program for causing a computer to obtain first order reversal curve (FORC) distributions of a sample using magnetization data received from a magnetometer, the computer program being embodied on the computer-readable medium and including instructions that, when executed, cause the computer to:
fit the magnetization data to obtain a fitting formula;
interpolate missing data using the obtained fitting formula; and
calculate the FORC distribution.

14. The article of manufacture according to claim 13, wherein the fitting formula is obtained by a spline fitting method.

15. The article of manufacture according to claim 13, wherein calculating the FORC distribution is done by calculating a mixed second derivative of the fitting formula in each data point.

16. The article of manufacture according to claim 13, wherein the magnetometer is a vibrating sample magnetometer.
